(19) United States
(12) Patent Application Publication
(10) Pub. No.: US 2006/0197202 A1
(43) Pub. Date: Sep. 7, 2006

(54) PHOTO DETECTOR PACKAGE

(76) Inventors: Jaw-Juinn Horng, Hsinchu (TW); Shih-Chang Shei, Tainan (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/164,966

(22) Filed: Dec. 13, 2005

(30) Foreign Application Priority Data
Dec. 13, 2004 (TW) 93138546

(51) Int. Cl. H01L 23/02

(52) U.S. Cl. 257/678

(57) ABSTRACT

A photo detector package is provided. The photo detector package includes a carrier, a photo sensor and a calibration module. The photo sensor having an active surface is disposed on the carrier. The calibration module is disposed on the carrier. The calibration module is electrically connected to the photo sensor. Moreover, the photo detector package described above can precisely detect the intensity of a light source (radiation) to be measured.

### CROSS-REFERENCE TO RELATED APPLICATION

This application claims the priority benefit of Taiwan application serial no. 93138546, filed on Dec. 13, 2005. All disclosure of the Taiwan application is incorporated herein by reference.

### BACKGROUND OF THE INVENTION

1. Field of Invention

The present invention relates to a detector package. More particularly, the present invention relates to a photo detector package.

2. Description of Related Art

When light projects on a photosensitive material, the light will activate the photosensitive material and facilitate the photosensitive material emitting electrons, such effect is called photoelectric effect. The products which the photoelectric effect is applied are, for example, solar cell and photo sensor.

The photo sensor is used to receive a photo signal and convert received photo signal into an electric signal (e.g. a current). The electric signal generated by the photo sensor is transferred to other components by a circuit board for further processing. In general, the photo sensor is packaged in a package to prevent the photo sensor from the pollution from outside environment.

FIG. 1 is a schematic cross-sectional view of a conventional photo detector package. Referring to FIG. 1, the photo detector package 100 mainly comprises a circuit board 110, a photo sensor 120 and a transparent encapsulant 130; the photo sensor 120 is electrically connected to the circuit board 110 by a plurality of bonding wires 140. As the photo sensor 120 is packaged in the transparent encapsulant 130, the light outside the photo detector package 100 can reach an active surface 122 of the photo sensor 120 by propagating through the transparent encapsulant 130. When the active surface 122 of the photo sensor 120 is irradiated by the external light, the photo sensor 120 will generate corresponding current according to the intensity of external light. The user can evaluate the intensity of light irradiated to the photo sensor 120 according to the value of current generated by the photo detector 120.

After measuring the current, the user judges the intensity of light irradiated to the active surface 122 of the photo sensor 120 according to a group of corresponding relationships between the intensity of the light and the current value. However, when the photo sensor 120 is produced by mass production, the corresponding relationships between the intensity of the light and the current value for different photo detectors 120 may not be the same. Moreover, before and after packing, the measured corresponding relationships between the intensity of the light and the current value may not be the same as well. Therefore, during measuring the photo detector 120, if the corresponding relationships between the intensity of the light and the current value the user used are not in consistency with that of the actual photo detector 120, a significant measuring error will occur.

### SUMMARY OF THE INVENTION

Accordingly, the present invention is directed to provide a photo detector package, which can maintain certain measuring accuracy during the measurement of the photo detector package.

The present invention provides a photo detector package. The photo detector package includes a carrier, a photo sensor and a calibration module. The photo sensor having an active surface is disposed on the carrier. In addition, the calibration module is disposed on the carrier and the calibration module is electrically connected to the photo sensor.

The photo detector package according to an embodiment of the present invention, wherein the carrier includes, for example, a circuit board, a packing substrate or a leadframe.

The photo detector package according to an embodiment of the present invention, wherein the photo sensor includes, for example, ultraviolet light sensor, infrared light sensor or visible light sensor.

The photo detector package according to an embodiment of the present invention further includes, for example, a plurality of bonding wires or bumps which are connected between the photo sensor and the carrier.

The photo detector package according to an embodiment of the present invention further includes a plurality of bonding wires which are connected between the photo sensor and the calibration module.

The photo detector package according to an embodiment of the present invention, wherein the calibration module includes a calibration processor and a memory. The calibration processor is electrically connected to the photo sensor, while the memory is electrically connected to the calibration processor. Wherein the photo sensor is used to sense a calibration light emitted by a calibration light source so as to output a corresponding calibration signal to the calibration processor, and then the calibration processor records the intensity of calibration light and the calibration signal in the memory.

The photo detector package according to an embodiment of the present invention further includes a judging processor which is electrically connected to the photo sensor and the memory. Wherein, the photo sensor is used to sense a light to be measured emitted by a light source to be measured so as to output a corresponding signal to be measured to the judging processor, and then the judging processor compares the signal to be measured with the calibration signal and outputs a parameter which represents the intensity of light to be measured.

The photo detector package according to an embodiment of the present invention further includes a plurality of bonding wires or bumps which are connected between the judging processor and the carrier.

The photo detector package according to an embodiment of the present invention, wherein the judging processor and the calibration module are integrated in a chip.

The photo detector package according to an embodiment of the present invention, wherein the calibration module is a chip having CMOS (Complementary Metal-Oxide-Silicon) devices or a chip having bipolar junction transistors.

The photo detector package according to an embodiment of the present invention further includes a plurality of bonding wires or bumps which are connected between the calibration module and the carrier.

The photo detector package according to an embodiment of the present invention further includes an encapsulant disposed on the carrier; the encapsulant encapsulates the photo sensor and the calibration module and exposes the active surface of the photo sensor.

The photo detector package according to an embodiment of the present invention, wherein the photo sensor stacks on the calibration module.

The photo detector package according to an embodiment of the present invention further includes an image output module which is disposed on the carrier.

The photo detector package according to an embodiment of the present invention, wherein the image output module includes a data processor and a driver IC.

The photo detector package according to an embodiment of the present invention, wherein the driver IC includes an LCD driver IC.

The photo detector package according to an embodiment of the present invention, wherein the driver IC includes an LED driver IC.

The photo detector package according to an embodiment of the present invention further includes a plurality of bonding wires or bumps which are connected between the image output module and the carrier.

The photo detector package according to an embodiment of the present invention further includes a plurality of bonding wires which are connected between the image output module and the carrier.

The photo detector package according to an embodiment of the present invention, wherein the image output module and the calibration module are integrated in a chip.

The photo detector package according to an embodiment of the present invention further includes a plurality of external terminals which are electrically connected to the photo sensor and the calibration module.

Thus, the photo sensor and the calibration module are packaged together in the present invention; the memory of the calibration module records the intensity of calibration light and the calibration signal corresponding to the intensity of calibration light in the memory. After comparing a signal to be measured generated by a light to be measured with the calibration signal stored in memory, the judging processor outputs a parameter representing the intensity of light to be measured to the image output module. Therefore, the photo detector package of the present invention can maintain certain measuring accuracy during the measurement.

In order to the make the aforementioned and other objects, features and advantages of the present invention comprehensible, an embodiment accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a conventional photo detector package.

FIG. 2 is a perspective view of the photo detector package according to the first embodiment of the present invention.

FIG. 3A is a schematic cross-sectional view of the photo detector package according to the first embodiment of the present invention.

FIG. 3B is another schematic cross-sectional view of the photo detector package according to the first embodiment of the present invention.

FIG. 4 is a circuit diagram of a photo detector shown in FIG. 3.

FIG. 5 is a schematic drawing when the photo detector package is moved under the light source to be measured.

FIG. 6A is a schematic cross-sectional view of the photo detector package according to the third embodiment of the present invention.

FIG. 6B is a schematic cross-sectional view of the photo detector package according to the fourth embodiment of the present invention.

FIG. 7 is a circuit diagram of a photo detector of an alternately embodiment of the present invention.

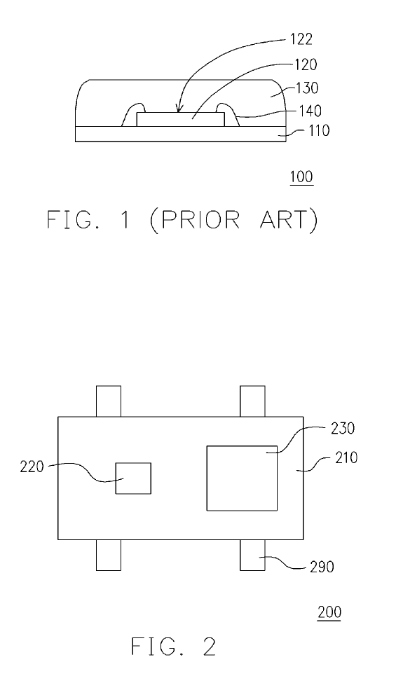

### DESCRIPTION OF EMBODIMENTS

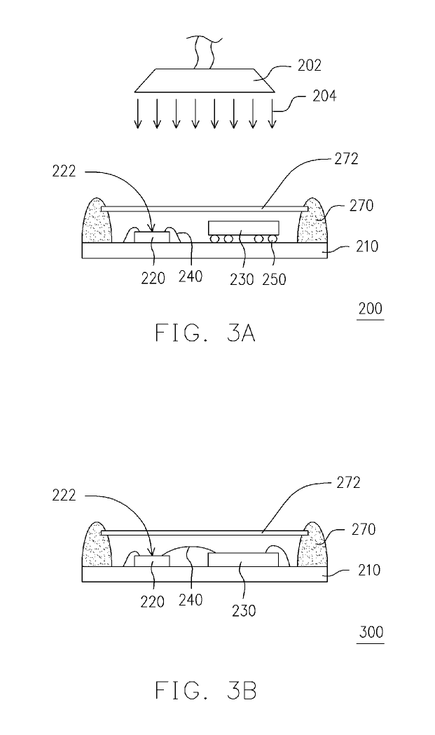

FIG. 2 is a perspective view of the photo detector package according to the first embodiment of the present invention and FIG. 3A is a sectional view of the photo detector package shown in FIG. 2. Referring to FIG. 2 and FIG. 3A, the photo detector package 200 of the present invention includes a carrier 210, a photo sensor 220 and a calibration module 230. The calibration module 230 is disposed on the carrier 210 and electrically connected to the photo sensor 220 by the carrier 210. Moreover, the photo detector package 200 may further includes a plurality of external terminals 290, such as pins, contact pads, bumps or other types of contacts. The external terminals 290 are electrically connected to the photo sensor 220 and the calibration module 230 by the carrier 210.

In an embodiment of the present invention, the carrier 210 may be, for example, a circuit board, a packing substrate or a leadframe. The photo sensor 220 having an active surface 222 is disposed on the carrier and may be an ultraviolet light sensor, an infrared light sensor or a visible light sensor. Moreover, the calibration module 230, for example, is a chip having CMOS (Complementary Metal-Oxide-Silicon) devices or a chip having bipolar junction transistors.

Referring to FIG. 3A, in an embodiment of the present invention, the photo detector package 200 may further includes a plurality of bonding wires 240 and bumps 250. The bumps 250 have electrical conductivity are adhered to the input/output terminals of the calibration module 230 to make the calibration module 230 connect to the carrier 210. The function of the bumps 250 is to output the signal of the calibration module 230 or input the external signal into the calibration module 230. Herein, the connection method between the calibration module 230 and the carrier 210 is called Flip Chip Interconnect Technology. In addition, the bonding wires 240 are connected between the photo sensor 220 and the carrier 210. The function of the bonding wires 240 is to output the signal of the photo sensor 220 or input the external signal into the photo sensor 220. Herein, the connection method between the photo sensor 220 and the carrier 210 is called Wire-Bond Technology. However, the photo sensor 220 can also connect to the carrier 210 by the method of Flip Chip Interconnect Technology, while the calibration module 230 can also connect to the carrier 210 by Wire-Bond Technology.

Referring to FIG. 3A, in an embodiment, the photo detector package 200 may further includes an encapsulant 270 and a cover plate 272 (e.g. glass cover plate); the substance of the encapsulant 270 is, for example, epoxy resin or polyimide. The encapsulant 270 disposed on the carrier 210 encapsulates the photo sensor 220 and the calibration module 230 while exposing the active surface 222 of the photo sensor 220, so that the active surface 222 can receive external light. The cover plate 272 is supported by the encapsulant 270 and disposed above the photo sensor 220 to prevent the photo sensor 220 from the pollution from outside environment. Of course, the photo sensor 220 can also be packaged by a transparent encapsulant; as the transparent encapsulant allows light to pass through so that it can completely encapsulate the photo sensor 220, and thus disposition of the cover plate 272 is not required any more.

FIG. 3B is a schematic cross-sectional view of the photo detector package according to the first embodiment of the present invention. The difference between the photo detector package 300 and the photo detector package 200 shown in FIG. 3A is that the calibration module 230 of the present invention is electrically connected to the carrier 210 by some of the bonding wires 240, while the photo sensor 220 is electrically connected to the calibration module 230 directly by some of the bonding wires 240, not by the carrier 210. The electrical connections between the calibration module 230 and the carrier 210 shown in FIG. 3A and FIG. 3B are only for illustrated, other possible electrical connections may be utilized between the calibration module 230 and the carrier 210.

In order to give a more detailed explanation to the operation relations between various components, the explanation will be given below together with a schematic drawing of the photo detector package 200 shown in FIG. 3A.

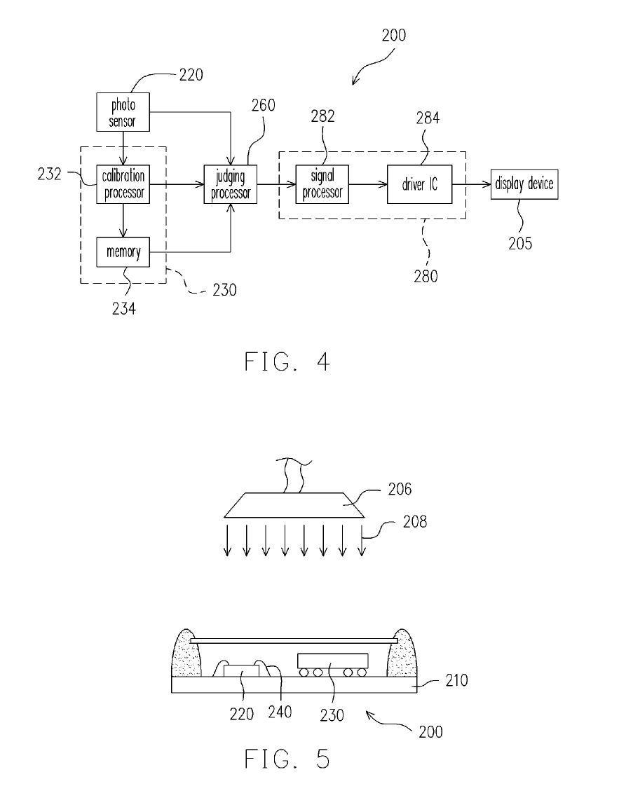

FIG. 4 is a circuit diagram of a photo detector package shown in FIG. 3. Referring to FIG. 3A and FIG. 4, in an embodiment, the photo detector package 200 may further includes a judging processor 260 and an image output module 280. The judging processor 260 and the image output module 280 are integrated together with the calibration module 230 in a chip by the method of System On Chip (SOC). However, the judging processor 260 and the image output module 280 can also be integrated in different chips with various functions respectively, and then connected to the carrier 210 by Flip Chip Interconnect Technology or Wire-Bond Technology.

Referring to FIG. 3A and FIG. 4, the calibration module 230 may includes a calibration processor 232 and a memory 234. The calibration processor 232 is electrically connected to the photo sensor 220, while the memory 234 is electrically connected to the calibration processor 232. In FIG. 3A, the calibration processor 232 and the memory 234 are integrated together to form a calibration module 230 by the method of SOC. However, the calibration processor 232 and the memory 234 can also be integrated into different chips with various functions respectively.

After the manufacturing production of the photo detector package 200 is completed, the calibration from a calibration light source 202 is required, and the corresponding relationships between the intensity of light and the calibration signal generated by the photo sensor 220 can be stored in the memory 234. The detailed description of the calibration flow will be given below.

Still referring to FIG. 3A and FIG. 4, first, the photo detector package 200 is disposed under the calibration light source 202 whose light intensity can be systematically adjusted by phase. When the photo sensor 220 senses a calibration light 204 emitted by the calibration light source 202, it will output a corresponding calibration signal (such as a current) to the calibration processor 232, and the calibration processor 232 will record the intensity of calibration light 204 and the corresponding calibration signal into the memory 234.

Then, adjust the intensity of calibration light 204 emitted by the calibration light source 202; the photo sensor 220 will output another calibration signal to the calibration processor 232, and the calibration processor 232 will also record the intensity of calibration light 204 and the new calibration signal into the memory 234. After repeating the above steps many times, there will be a lot of groups of the intensity of calibration light 204 and the corresponding calibration signals recorded in the memory 234.

After completing the calibration, the photo detector package 200 can be moved under the light source to be sensed to perform measurement of the intensity of light. The detailed explanation for the flow of sensing light source will be given below.

FIG. 5 is a schematic drawing when the photo detector package shown in FIG. 3A is disposed under a light source to be measured. Referring to FIG. 4 and FIG. 5, the light source to be measured 206 is any kind of the light sources to be measured, for example, a light source to generate ultraviolet light. When the photo sensor 220 is placed under the light source to be measured 206 and senses a light to be measured 208 emitted by the light source to be measured 206, the photo sensor 220 will output a corresponding signal to be measured (such as the value of current) to the judging processor 260, and then the judging processor 260 will capture a calibration signal from the memory 234 of the calibration module 230 and compare the signal to be measured with the calibration signal. When the judging processor 260 gets a calibration signal closest to the signal to be measured by the comparison, the judging processor 260 will output a parameter to the image output module 280; the parameter represents the value of intensity of light of the calibration signal.

In an embodiment, the image output module 280 includes a signal processor 282 and a driver IC 284. The driver IC 284 includes, for example, LCD driver IC or LED driver IC. When the parameter representing the value of intensity of light to be measured outputs to the image output module 280, the signal processor 282 will convert the parameter representing the intensity of light to be measured 208 into an image signal. Then, the signal processor 282 will output the image signal to the driver IC 284, and then the driver IC 284 will output a driver signal and the image signal to a display device 205. The display device 205 includes a display or an LED. At this moment, the display device 205 will display the intensity of light source to be measured 206 sensed by the photo sensor 220, so that the user can read conveniently.

Furthermore, in FIG. 5, the signal processor 282 and the driver IC 284 are integrated together to form the image output module 280 by the method of SOC. However, the signal processor 282 and the driver IC 284 can also be integrated into different chips respectively.

In addition, in FIG. 5, the photo detector package 200 in FIG. 3A is used to measure a light source to be measured, the photo detector package 300 in FIG. 3B can be used, too; as the operation principles are the same, the details are not provided any more herein.

Of course, the arrangement of the components in the photo detector package 200 is not limited as shown in FIG. 3A, other suitable arrangement ways are applicable to the present invention too. The explanation will be given below together with other embodiments.

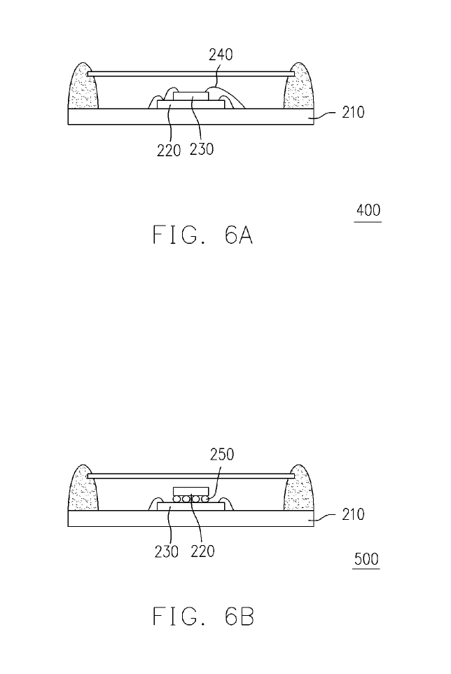

FIG. 6A is a schematic cross-sectional view of the photo detector package according to the third embodiment of the present invention, FIG. 6B is a schematic cross-sectional view of the photo detector package according to the fourth embodiment of the present invention. Referring to FIG. 6A first, the difference between the photo detector package 400 and the photo detector package 200 of the first embodiment is: the photo sensor 220 stacks on the calibration module 230, and the photo sensor 220 is electrically connected to the calibration module 230 directly by part of the bonding wires 240, not by the carrier 210. Then referring to FIG. 6B, the difference between the photo detector package 500 and the photo detector package 200 of the first embodiment is: the photo sensor 220 stacks on the calibration module 230, and the photo sensor 220 is electrically connected to the calibration module 230 directly by the bumps 250, not by the carrier 210. Therefore, the photo detector package 400 and the photo detector package 500 can reduce the carrying area of the carrier 210. As the other components and operation method are introduced in the first embodiment, the details are not provided any more herein.

In the photo detector package of the present invention, the measuring inaccuracy can be minimized. Specifically, measuring inaccuracy resulted from transmittance loss of the cover plate 272 (e.g. glass cover plate), response of the photo sensor 220 and so on could be calibrated precisely. It should be noted that the architecture of the photo detector package 200 can be applied to different applications such as UV detector, IR detector, optical communication receiver, or other similar components. In addition, calibration procedure of the photo detector package 200 of the present invention can be performed any time, for example, after a final product is completed, or during the product is fabricated. Moreover, not only the cover glass loss or any shadow loss of per photo detector package 200 described above can be calibrated precisely, but also the photo sensor variation thereof can be minimized by the calibration module 230.

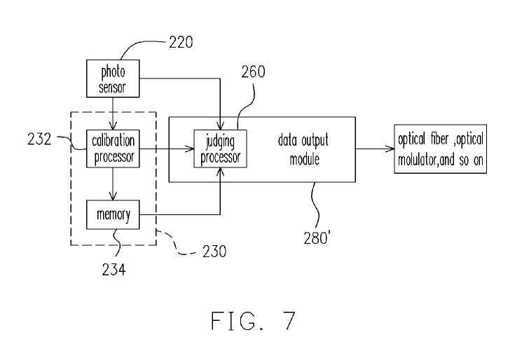

FIG. 7 is a circuit diagram of a photo detector of an alternately embodiment of the present invention. Referring to FIG. 7, the photo detector package 200 can be applied to optical communication applications. In detail, when the photo detector package 200 is used as an optical communication receiver, instead of an image output module 280, a data output module 280′ (e.g. a digital signal processor (DSP)) including the judging processor 260 is provided. In the present embodiment, the judging processor 260 of the data output module 280′ can verify the data format (e.g. QAM, PSK, and OOK etc.) represented by the light 208. In this case, the signal output by the data output module 280′ is not delivered to the display device 205, instead, the signal output by the data output module 280′ is delivered to devices with predetermined functions, such as optical fibers, optical modulator, and so on.

In conclusion, a photo sensor and a calibration module of a photo detector package are packaged together in the present invention, and after the photo detector package is calibrated by a calibration light source; a memory of a calibration module records the intensity of calibration light and a calibration signal into the memory; during measuring the intensity of light source to be measured, a judging processor compares a signal to be measured with the calibration signal and outputs a parameter representing the intensity of light to be measured to an image output module. Therefore, the photo detector package of the present invention can improve measuring accuracy of the intensity of light source during the measurement of the intensity of light source to be measured. Moreover, in the photo detector package of the second embodiment of the present invention, the photo sensor stacks on the calibration module, so that the carrying area of the carrier of the photo detector package can be reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A photo detector package, comprising:
a carrier;
a photo sensor having an active surface, wherein the photo sensor is disposed on the carrier; and
a calibration module disposed on the carrier wherein the calibration module is electrically connected to the photo sensor.

2. The photo detector package as claimed in claim 1, wherein the carrier comprises a circuit board, a packing substrate or a leadframe.

3. The photo detector package as claimed in claim 1, wherein the photo sensor comprises ultraviolet light sensor, infrared light sensor or visible light sensor.

4. The photo detector package as claimed in claim 1 further comprising a plurality of bonding wires or bumps connected between the photo sensor and the carrier.

5. The photo detector package as claimed in claim 1 further comprising a plurality of bonding wires connected between the calibration module and the photo sensor.

6. The photo detector package as claimed in claim 1, wherein the calibration module comprises:
a calibration processor electrically connected to the photo sensor; and
a memory electrically connected to the calibration processor, wherein the photo sensor is suitable for sensing a calibration light emitted by a calibration light source so as to output a corresponding calibration signal to the calibration processor, and the calibration processor is suitable for recording the intensity of the calibration light and the calibration signal in the memory.

7. The photo detector package as claimed in claim 6 further comprising a judging processor electrically connected to the photo sensor and the memory, wherein the photo sensor is suitable for sensing a light to be measured emitted by a light source to be measured so as to output a corresponding signal to be measured to the judging processor, and the judging processor is suitable for comparing the signal to be measured with the calibration signal and outputs a parameter which represents the intensity of the light to be measured.

8. The photo detector package as claimed in claim 7 further comprising a plurality of bonding wires or bumps connected between the judging processor and the carrier.

9. The photo detector package as claimed in claim 7, wherein the judging processor and the calibration module are integrated in a chip.

10. The photo detector package as claimed in claim 1, wherein the calibration module is a chip having complementary metal-oxide-silicon devices or a a chip having bipolar junction transistors.

11. The photo detector package as claimed in claim 1 further comprising a plurality of bonding wires or bumps connected between the calibration module and the carrier.

12. The photo detector package as claimed in claim 1 further comprising an encapsulant disposed on the carrier and encapsulates the photo sensor and the calibration module while exposing the active surface of the photo sensor.

13. The photo detector package as claimed in claim 1, wherein the photo sensor stacks on the calibration module.

14. The photo detector package as claimed in claim 1 further comprising an image output module disposed on the carrier.

15. The photo detector package as claimed in claim 14, wherein the image output module comprises:
a data processor; and
a driver IC.

16. The photo detector package as claimed in claim 15, wherein the driver IC comprises an LCD driver IC.

17. The photo detector package as claimed in claim 15, wherein the driver IC comprises an LED driver IC.

18. The photo detector package as claimed in claim 16 further comprising a plurality of bonding wires or bumps connected between the image output module and the carrier.

19. The photo detector package as claimed in claim 14, wherein the image output module and the calibration module are integrated in a chip.

20. The photo detector package as claimed in claim 1 further comprising:
an image output module disposed on the carrier; and
a judging processor disposed on the carrier.

21. The photo detector package as claimed in claim 20, wherein the image output module and the judging processor are integrated in a chip.

22. The photo detector package as claimed in claim 20 further comprising a plurality of external terminals electrically connected to the photo sensor and the calibration module.
